(19) United States
(12) Patent Application Publication
(10) Pub. No.: US 2003/0164727 A1
(43) Pub. Date: Sep. 4, 2003

(54) Power supply device, transistor driving method, recording medium

(76) Inventor: Kazuo Sudo, Kanagawa (JP)

Correspondence Address: Jay H Maioli, Cooper & Dunham, 1185 Avenue of the Americas, New York, NY, 10036, US

(21) Appl. No.: 10/182,689

(22) PCT Filed: Nov. 29, 2001
(86) PCT No.: PCT/JP01/10414

(30) Foreign Application Priority Data
Dec. 5, 2000 (JP) 2000-369956

(51) Int. Cl. H03K 17/60

(52) U.S. Cl. 327/478

(57) ABSTRACT

The present invention provides a power supply unit (regulator circuit) capable of preventing thermal breakdown of a driven transistor that may be caused accidentally in case the collector output of the transistor is grounded. A power supply unit (10) for supplying a driving current to a base of a transistor (20) to thereby drive the same has a lower threshold comparator (14) which compares an actual collector output Vin of the transistor (20) with a lower threshold of 0.5 Vref, and sends a stop signal to a current controller (18) if the collector output Vin is less than the lower threshold of 0.5 Vref. Thus, when the collector output of the transistor (20) is grounded directly without via a load circuit (40), the collector output Vin is rendered under the lower threshold of 0.5 Vref, so that the current controller (18) receives the stop signal from the lower threshold comparator (14) and then stops the supply of the driving current to the transistor (20). Consequently, it becomes possible to prevent thermal breakdown of the transistor (20) that may otherwise be caused by any excessive supply of the driving current.

### TECHNICAL FIELD

The present invention relates to a power supply unit (regulator circuit) for a transistor which is a subject to be driven.

### BACKGROUND ART

There has been known heretofore a regulator circuit for controlling the collector output voltage of a transistor which is a subject to be driven. The regulator circuit adjusts the base current of a driven transistor by comparing the actual value of the collector output voltage with a desired target value thereof. The collector output voltage can be raised by increasing the base current, or it can be lowered by decreasing the base current.

However, if the collector is grounded accidentally due to some reason, a problem arises in the conventional regulator circuit. That is, since the collector output voltage fails to be raised even by increasing the base current, the regulator circuit keeps increase of the base current in succession to consequently generate heat in the transistor to be driven. And when the loss has exceeded its allowable limit, the driven transistor comes to break down.

In view of the problem mentioned above, it is an object of the present invention to provide an improved regulator circuit (power supply unit) and so forth capable of preventing thermal breakdown of a driven transistor that may be caused when the collector (secondary) output thereof has been grounded accidentally.

### DISCLOSURE OF THE INVENTION

The present invention is concerned with a power supply unit for supplying a driving current to a transistor to thereby drive the same. The invention comprises a lower threshold calculator means, a lower threshold comparator means and a current control means.

The lower threshold calculator means calculates, in accordance with a desired target output of the driven transistor, a lower threshold of the output. The lower threshold comparator means compares the actual output of the transistor with the lower threshold. And the current control means stops supply of the driving current if the actual output of the transistor is less than the lower threshold.

According to the power supply unit having such a circuit configuration, when the actual output of the transistor has become less than the lower threshold due to accidental grounding or the like of the transistor output, then the current control means stops supply of the driving current to the transistor. Therefore, it is possible to prevent thermal breakdown of the transistor that may otherwise be caused by any excessive supply of the driving current.

Preferably the power supply unit of the present invention further comprises a timer. The timer is started when the actual output of the transistor has become less than the lower threshold and, after a lapse of a fixed time from the start, gives a notice indicating such a lapse. More preferably, the current control means stops supply of the driving current in case the actual output of the transistor is kept under the lower threshold continuously until reception of the notice from the start of the timer.

It may occur that, even though the output of the transistor is not grounded, the actual output thereof is temporarily reduced to be under the lower threshold. Therefore, in case the actual output is continuously kept under the lower threshold even after a lapse of the fixed time posterior to reduction of the actual output under the lower threshold, then it is not regarded as a temporal phenomenon. In such a case, the current control means is enabled to stop the supply of the driving current to the transistor, whereby the supply of the driving current can be brought to a halt when the output of the transistor is really grounded or the like.

More preferably, the power supply unit of the present invention may further comprise a voltage comparator means which compares the actual output of the transistor with a desired target output thereof. In this case, the current control means regulates the supply amount of the driving current in accordance with the comparison result obtained from the voltage comparator means.

It is also preferred that the power supply unit is composed of an IC (integrated circuit), and the transistor is positioned outside the IC.

The provision of such an IC outside the transistor is advantageous for radiation of heat in the transistor.

### BRIEF DESCRIPTION OF THE DRAWINGS

FIG. 1 is a block diagram showing the structure of a transistor driving circuit with an incorporated power supply unit which represents a first embodiment of the present invention;

FIG. 2 is a flowchart showing the operation of the transistor driving circuit with the incorporated power supply unit representing the first embodiment of the present invention; and

FIG. 3 is a block diagram showing the structure of another transistor driving circuit with an incorporated power supply unit which represents a second embodiment of the present invention.

### BEST EMBODIMENTS OF THE INVENTION

Hereinafter some embodiments of the present invention will be described in detail with reference to the accompanying drawings.

First Embodiment

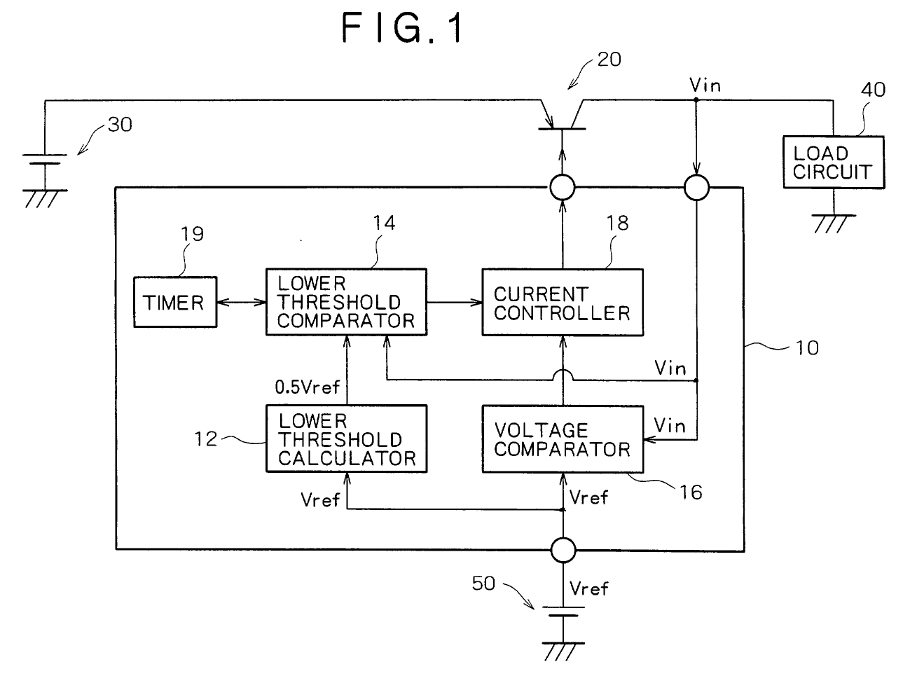

FIG. 1 is a block diagram showing the structure of a transistor driving circuit with an incorporated power supply unit which represents a first embodiment of the present invention.

This transistor driving circuit comprises a power supply unit 10, a transistor 20, a battery 30, a load circuit 40 and a reference voltage source 50.

The power supply unit 10 is a regulating circuit to drive the transistor 20 by supplying a driving current to a base terminal of the transistor 20. The power supply unit 10 is used for maintaining the collector output voltage of the transistor 20 constant. The power supply unit 10 acquires the collector output voltage Vin from the collector terminal of the transistor 20. The driving current is determined on the basis of the collector output voltage and so forth. The internal structure of the power supply unit 10 will be described in detail later. The power supply unit 10 itself is composed of an IC (integrated circuit).

The transistor 20 is a subject transistor to be driven. The emitter terminal of the transistor 20 is connected to the battery 30, the collector terminal thereof to the load circuit 40, and the base terminal thereof to the power supply unit 10, respectively. The collector output voltage Vin can be raised by increasing the driving current supplied to the base terminal, while the collector output voltage Vin can be lowered by decreasing the driving current. The transistor 20 is positioned outside the power supply unit 10 which is composed of an IC.

The battery 30 is a power source for applying a DC voltage to the transistor 20. The load circuit 40 is a circuit to receive the collector output of the transistor 20, and it is grounded. Normally the collector terminal of the transistor 20 is grounded via the load circuit 40. Occasionally, however, the collector terminal is grounded directly. In such a case, the collector output voltage Vin fails to be raised despite increase of the driving current.

The reference voltage source 50 serves as a power source for delivering, to the power supply unit 10, a desired target output required for the transistor 20. More specifically, the power supply unit 10 supplies a driving current to the base terminal of the transistor 20 in such a manner that the voltage Vref (desired target output) of the reference voltage source 50 becomes equal to the voltage outputted from the collector terminal of the transistor 20.

Now an explanation will be given on the internal structure of the power supply unit 10 with reference to FIG. 1. The power supply unit 10 has a lower threshold calculator 12, a lower threshold comparator 14, a voltage comparator 16, a current controller 18 and a timer 19.

The lower threshold calculator 12 calculates a lower threshold in accordance with the voltage Vref (desired target output) of the reference voltage source 50. For example, the lower threshold has a value of 0.5 Vref. The lower threshold is settable to any arbitrary value, or may have the following property. First, when there occurs that the collector terminal is grounded directly or the like, the collector output voltage Vin is rendered under the lower threshold. However, in any other case, the collector output voltage Vin exceeds the lower threshold.

The lower threshold comparator 14 compares the collector output voltage Vin with the lower threshold (e.g., 0.5 Vref). And if the result of this comparison signifies that the collector output voltage Vin is less than the lower threshold, the lower threshold comparator 14 sends a stop signal to the current controller 18. The circuit may be so modified that, if the collector output voltage Vin is kept under the lower threshold continuously until reception of a notice indicating a lapse of a fixed time after start of the timer 19, then the lower threshold comparator 14 sends a stop signal to the current controller 18.

The voltage comparator 16 compares the voltage Vref (target output) of the reference voltage source 50 with the collector output voltage Vin. And in response to the comparison result obtained from the voltage comparator 16, the current controller 18 supplies a driving current to the base terminal of the transistor 20. More specifically, if the comparison result signifies that Vin is higher than Vref, the driving current is decreased. To the contrary, if Vin is lower than Vref, the driving current is increased. The driving current may be increased or decreased by a fixed amount each time, or may be set in accordance with the difference between Vin and Vref. That is, the increment or decrement of the driving current may be determined on the basis of the comparison result obtained from the voltage comparator 16. In response to the stop signal sent from the lower threshold comparator 14, the current controller 18 stops supply of the driving current to the base terminal of the transistor 20.

The timer 19 is started upon detection that, in response to the signal from the lower threshold comparator 14, the collector output voltage Vin has become less than the lower threshold. Then, after a lapse of the fixed time from such start, the timer 19 notifies the lower threshold comparator 14 of the detection.

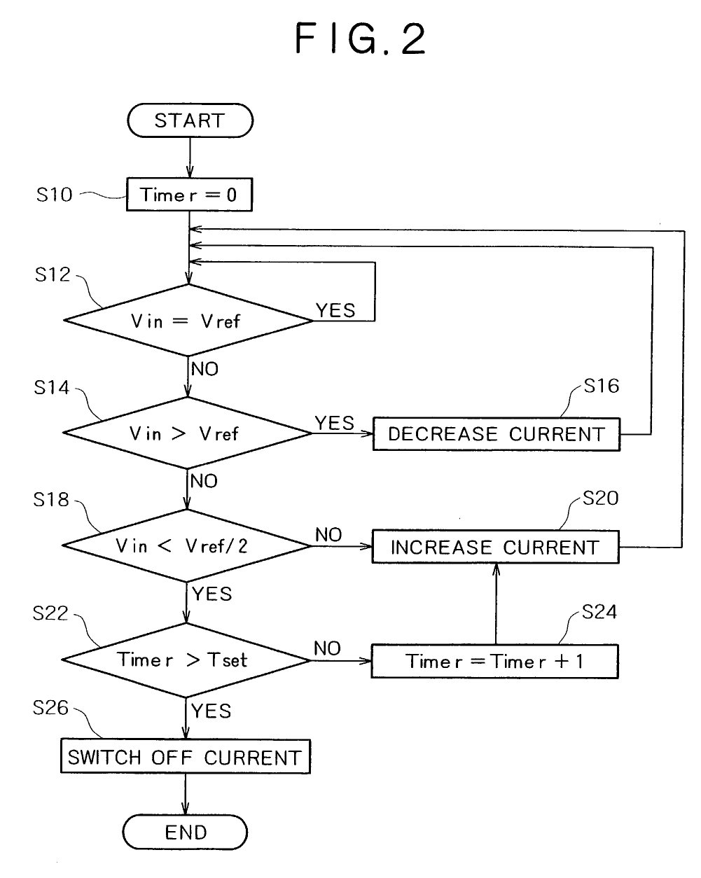

Next, the operation performed in the first embodiment of the present invention will be described below with reference to a flowchart of FIG. 2. First, the timer 19 is set to time 0 without being started. Supposing now that the time to be measured by the timer 19 is termed “Timer” here, “Timer” is set to 0 (S10). At this step, the voltage comparator 16 compares the collector output voltage Vin with the voltage Vref (desired target output) of the reference voltage source 50. And if the result of such comparison signifies that Vin is equal to Vref (S12, Yes), the purpose of using the power supply unit 10 has already been achieved, and therefore the present state is maintained, and a subsequent comparison of Vin with Vref is executed in succession (S12).

Meanwhile, if the result of such comparison signifies that Vin is not equal to Vref (S12, No), it may be considered that Vin is greater than Vref (S14, Yes). In this case, the current controller 18 decreases the driving current supplied to the base terminal (S16). The decrement of the driving current may be a fixed amount, or may be determined in accordance with the difference between Vin and Vref. And then the operation returns to the comparison of Vin with Vref (S12).

In case Vin is not greater than Vref (S14, No), it follows that Vin is smaller than Vref. In this case, the operation is different depending on the numerical relationship between Vin and the lower threshold of 0.5 Vref.

The lower threshold calculator 12 calculates the lower threshold on the basis of the voltage Vref of the reference voltage source 50. For example, the lower threshold has a value of 0.5 Vref. The lower threshold comparator 14 compares the collector output voltage Vin with the lower threshold (e.g. , 0.5 Vref) (S18). And if the result of such comparison signifies that Vin is more than the lower threshold of 0.5 Vref (S18, No), the lower threshold comparator 14 does not send a stop signal to the current controller 18. Then the current controller 18 increases the driving current supplied to the base terminal (S20). Thereafter the operation returns to the comparison of Vin with Vref (S12).

Meanwhile, if the result of the above comparison signifies that Vin is less than the lower threshold of 0.5 Vref (S18, Yes), there exists a possibility that the collector output of the transistor 20 is grounded directly. In a state where the collector output is grounded directly, Vin fails to be raised despite any increase of the driving current supplied to the base terminal. Therefore, in case Vin is kept under the lower threshold of 0.5 Vref continuously for a fixed time, it may be regarded as direct grounding of the collector output, and then supply of the driving current may be stopped.

When the result of the above comparison signifies that Vin is less than the lower threshold of 0.5 Vref (S18, Yes), the lower threshold comparator 14 makes a decision as to whether Timer has exceeded Tset (fixed time) or not (S22). This decision can be executed on the basis of whether a notice indicating an excess over the fixed time has been given from the timer 19 to the lower threshold comparator 14.

If Timer is not over Tset (fixed time) (S22, No), the lower threshold comparator 14 instructs the timer 19 to increase Timer by 1 (S24). Here, 1 denotes a unit of time such as 1 s, 1 ms and so forth. Then the current controller 18 increases the driving current supplied to the base terminal (S20). Thereafter the operation returns to the comparison of Vin with Vref (S12). When Timer has exceeded Tset (fixed time) (S22, Yes), the timer 19 notifies the lower threshold comparator 14 of a lapse of more than the fixed time, so that the lower threshold comparator 14 decides direct grounding of the collector output and then sends a stop signal to the current controller 18. Subsequently the current controller 18 stops supply of the driving current to the base terminal of the transistor 20 (S26).

More specifically, there may occur that the actual collector output Vin of the transistor 20 is temporarily reduced under the lower threshold of 0.5 Vref even when the collector output Vin is not grounded or the like. Therefore, in case the actual output Vin is kept under the lower threshold of 0.5 Vref continuously even after a lapse of the fixed time Tset posterior to reduction of the actual output Vin under the lower threshold of 0.5 Vref, this is not regarded as a temporal phenomenon.

In such a case, the current controller 18 is capable of stopping supply of the driving current to the transistor 20, whereby the supply of the driving current is brought to a halt when the output of the transistor 20 has been practically grounded or the like.

In this embodiment, the power supply unit 10 itself is composed of an IC, and the transistor 20 is positioned outside the IC power supply unit 10, so that an advantage is attainable in radiation of heat in the transistor 20.

Now an explanation will be given on the reason effected for positioning the transistor 20 outside the power supply unit 10 itself. According to the first embodiment, the power supply unit 10 is capable of deciding the driving current supplied to the transistor 20 if only Vin and Vref can be acquired. That is, the characteristic of the transistor 20 need not be known. Therefore, it becomes possible to provide the transistor 20 outside the power supply unit 10, and regardless of replacement or the like of the transistor 20, the power supply unit 10 is still capable of deciding the driving current supplied to the transistor 20.

The above merit is not achievable by a method which forms, in parallel with the transistor, a circuit where a current corresponding to 1/N of the load current flows, and then detects an excess of the driving current by monitoring such 1/N current. In this method, it is necessary that the characteristic of the transistor be known. Consequently, if external provision of the transistor is allowed, the transistor characteristic is changed as a result of its replacement or the like. Therefore, in this method, the transistor needs to be positioned within the power supply unit (regulator circuit) . However, incorporating the transistor therein is impossible due to the necessity of radiation of heat in the transistor.

According to the first embodiment, however, it becomes possible to position the transistor 20 outside the power supply unit 10.

Second Embodiment

A second embodiment is so structured as to form an electric hardware configuration out of the individual blocks in the first embodiment, wherein the timer 19 is omitted.

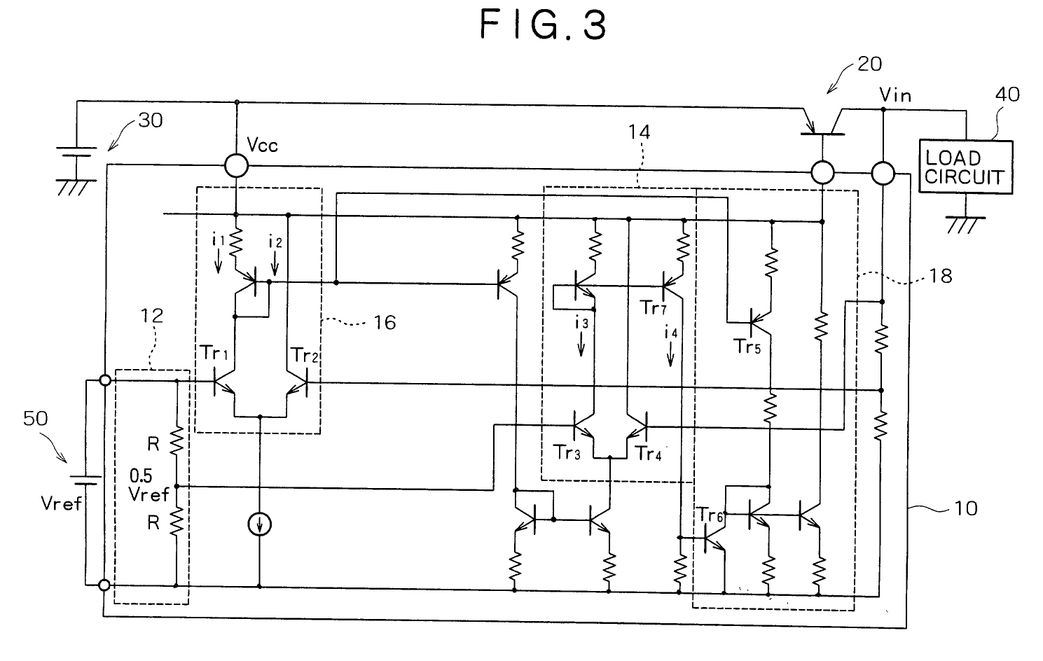

FIG. 3 is a circuit diagram showing the structure of a transistor driving circuit with an incorporated power supply unit related to the second embodiment of the invention. This transistor driving circuit comprises a power supply unit 10, a transistor 20, a battery 30, a load circuit 40 and a reference voltage source 50. The above transistor 20, battery 30, load circuit 40 and reference voltage source 50 are exactly the same as those used in the first embodiment.

The power supply unit 10 has a lower threshold calculator 12, a lower threshold comparator 14, a voltage comparator 16 and a current controller 18.

The lower threshold calculator 12 consists of two resistors R connected in series to each other. Both ends of the lower threshold calculator 12 are connected to the reference voltage source 50. And the potential obtained at the joint of the resistors R serves as a lower threshold of 0.5 Vref.

The lower threshold comparator 14 comprises two transistors Tr3 and Tr4. The joint having the potential of lower threshold 0.5 Vref is connected to the base of the transistor Tr3, and the collector output of the transistor 20 is connected to the base of the transistor Tr4, respectively. The emitter of the transistor Tr3 is connected to the emitter of the transistor Tr4.

The voltage comparator 16 comprises two transistors Tr1 and Tr2. The reference voltage source 50 is connected to the base of the transistor Tr1, and the collector output of the transistor 20 is connected to the base of the transistor Tr2. The emitter of the transistor Tr1 is connected to the emitter of the transistor Tr2. And the collector of the transistor Tr2 is connected to the battery 30.

The current controller 18 comprises two transistors Tr5 and Tr6. If the transistor Tr5 increases the collector current in response to the voltage comparator 16, it causes an increase of the supplied driving current to thereby raise the collector output Vin. When the transistor Tr6 is turned on, the supply of the driving current is brought to a stop.

For turning on the transistor Tr6, a current i4 needs to exceed a fixed value. And for increasing the current i4, it is necessary that the driving current of the transistor 20 be increased in response to the voltage comparator 16 and also that the collector output of the transistor 20 be under the lower threshold in the lower threshold comparator 14. The reason for permitting turn-on of the transistor Tr6 only in compliance with an increase of the driving current of the transistor 20 resides in preventing a malfunction that the lower threshold comparator 14 operates earlier at the time of initial switching on.

Next, an explanation will be given on the operation performed in the second embodiment of the present invention. Since the operation of the second embodiment is substantially similar to that of the first embodiment, it will be described below with reference to the flowchart of FIG. 2. However, as the timer 19 is not used in the second embodiment, there are omitted some steps of setting Timer to 0 (S10), deciding the numerical relationship between Timer and Tset (S22), and increasing Timer by 1 (S24).

First, the step of setting Timer to 0 (S10) is omitted, and the voltage comparator 16 compares the collector output voltage Vin with the voltage Vref (desired target output) of the reference voltage source 50. Such comparison is possible since Vref is supplied to the base of the transistor Tr1 while Vin is supplied to the base of the transistor Tr2. And if the result of this comparison signifies that Vin is equal to Vref (S12, Yes), the purpose of using the power supply unit 10 has already been achieved, and therefore the present state is maintained, and a subsequent comparison of Vin with Vref is executed in succession (S12).

Meanwhile, if the result of such comparison signifies that Vin is not equal to Vref (S12, No), it may be considered that Vin is greater than Vref (S14, Yes). In this case, the current controller 18 decreases the driving current supplied to the base terminal (S16). The decrement of the driving current may be a fixed amount, or may be determined in accordance with the difference between Vin and Vref. And then the operation returns to the comparison of Vin with Vref (S12).

In case Vin is not greater than Vref (S14, No), it follows that Vin is smaller than Vref. In this case, the operation is different depending on the numerical relationship between Vin and the lower threshold of 0.5 Vref.

The lower threshold calculator 12 calculates the lower threshold on the basis of the voltage Vref of the reference voltage source 50. In the circuit of FIG. 3 for example, the lower threshold has a value of 0.5 Vref. The lower threshold comparator 14 compares the collector output voltage Vin with the lower threshold (e.g., 0.5 Vref) (S18). This comparison is possible since the lower threshold of 0.5 Vref is supplied to the base of the transistor Tr3 while Vin is supplied to the base of the transistor Tr4. And if the result of such comparison signifies that Vin is more than the lower threshold of 0.5 Vref (S18, No), the lower threshold comparator 14 does not send a stop signal to the current controller 18. However, in the voltage comparator 16, a current i1 flows in the collector of the transistor Tr1, and a current i2 flows in the collector of the transistor Tr2. Consequently, the collector current of the transistor Tr5 in the current controller 18 is increased to thereby cause an increase of the driving current supplied to the base terminal of the transistor 20 (S20). Thereafter the operation returns to the comparison of Vin with Vref (S12).

Meanwhile, if the result of the above comparison signifies that Vin is less than the lower threshold of 0.5 Vref (S18, Yes), a current i3 flows in the collector of the transistor Tr3 in the lower threshold comparator 14, and a current i4 flows in the collector of the transistor Tr7. Consequently the transistor Tr6 in the current controller 18 is turned on, and the current controller 18 stops supply of the driving current to the base terminal of the transistor 20 (S26). In this embodiment, there are omitted the step of deciding the numerical relationship between Timer and Tset (S22), and the step of increasing Timer by 1 (S24). The currents i3 and i4 correspond to the stop signal sent from the lower threshold comparator 14.

In the second embodiment also, the same advantageous effects are attainable as well as in the first embodiment.

The embodiment mentioned above can be realized in the following manner. In a computer equipped with a CPU, a hard disk and a media (floppy disk, CD-ROM, etc.) reader, a medium, which contains a recorded program to realize each of the aforementioned blocks, particularly the component blocks of the power supply unit 10, is read out by the media reader and then is installed in the hard disk. The above-stated functions can be accomplished by such a method also.

According to the present invention, in case the output of the transistor is accidentally grounded for example, the actual output is rendered less than the lower threshold, so that the current control means stops supply of the driving current to the transistor, hence preventing thermal breakdown of the transistor that may otherwise be caused by an excessive increase of the driving current.

1. A power supply unit for supplying a driving current to a transistor to thereby drive said transistor, comprising:
lower threshold calculator means for calculating, in accordance with a desired target output of said transistor, a lower threshold of said output;
lower threshold comparator means for comparing the actual output of said transistor with the lower threshold; and
current control means for stopping the supply of the driving current if the actual output of said transistor is less than the lower threshold.

2. The power supply unit according to claim 1, further comprising a timer which is started upon reduction of the actual output of said transistor under the lower threshold and gives a notice after a lapse of a fixed time from the start, wherein said current control means stops the supply of the driving current if the actual output of said transistor is kept under the lower threshold continuously from the start of said timer to the reception of said notice.

3. The power supply unit according to claim 1 or 2, further comprising voltage comparator means for comparing the actual output of said transistor with the desired target output thereof, wherein said current control means regulates the supply amount of the driving current in accordance with the comparison result obtained from said voltage comparator means.

4. The power supply unit according to claim 1 or 2, wherein said power supply unit is composed of an IC, and said transistor is positioned outside the IC.

5. The power supply unit according to claim 1 or 2, further comprising voltage comparator means for comparing the actual output of said transistor with the desired target output thereof, wherein said current control means regulates the supply amount of the driving current in accordance with the comparison result obtained from said voltage comparator means, and said power supply unit is composed of an IC, and said transistor is positioned outside the IC.

6. A transistor driving method for driving a transistor by supplying a driving current to said transistor, comprising:
a step of calculating, in accordance with a desired target output of said transistor, a lower threshold of said output;
a step of comparing the actual output of said transistor with the lower threshold; and
a step of stopping the supply of the driving current if the actual output of said transistor is less than the lower threshold.

7. A recording medium readable by a computer and containing a recorded program adapted to execute, by the computer, a transistor driving routine which drives a transistor by supplying a driving current thereto, said program comprising:
a process of calculating, in accordance with a desired target output of said transistor, a lower threshold of said output;
a process of comparing the actual output of said transistor with the lower threshold; and
a process of stopping the supply of the driving current if the actual output of said transistor is less than the lower threshold.
